(19) United States
(12) Patent Application Publication
(10) Pub. No.: US 2026/0255696 A1
(43) Pub. Date: Aug. 27, 2026

(54) ASYMMETRIC PHOTOVOLTAIC MODULES WITH GLASS SUBSTRATES

(71) Applicant: CORNING INCORPORATED, CORNING, NY (US)

(72) Inventors: Oladapo Olalekan Bello, Horseheads, NY (US); Kurt Edward Gerber, Dansville, NY (US); Eric Scott Hamby, Pittsford, NY (US); Dhananjay Joshi, Rockville, MD (US)

(21) Appl. No.: 19/489,635

(22) PCT Filed: Jun. 13, 2024
(86) PCT No.: PCT/US2024/033702

§ 371 Date: Dec. 3, 2025

Related U.S. Application Data
(60) Provisional application No. 63/522,797, filed on Jun. 23, 2023.

(51) Int. Cl. H10F 19/80; H10K 30/50; H10K 30/88; H10K 39/00; H10K 39/15

(52) U.S. Cl. CPC H10F 19/807; H10F 19/804; H10K 30/50; H10K 30/88; H10K 39/15; H10K 39/601

(57) ABSTRACT

Various aspects of photovoltaic modules are provided herein, including: an outer glass layer, an inner glass layer, a PV structures disposed on the outer glass layer, and a polymeric encapsulant having a tailored thickness and tailored elastic modulus is disposed over the PV structures and between the inner and outer glass layers, where outer glass layer is at least three times thinner than the inner glass layer; such that the module exhibits a failure probability (P_{f}) of less than 15% when tested according to the IEC 61215 & ASTM E1038 Hail Test.

This application claims the benefit of priority under 35 U.S.C. § 119 of U.S. Provisional Application No. 63/522,797 filed Jun. 23, 2023, the content of which is incorporated herein by reference in its entirety.

### FIELD OF THE DISCLOSURE

The present disclosure relates to photovoltaic (PV) modules, particularly, solar modules for various end use applications, including utility, residential and commercial markets.

### BACKGROUND

Conventional PV modules are being successfully used today for various power generation applications. Demand for PV modules remains high, and only appears to be increasing, given the significant reduction in power generation-related emissions associated with this technology as compared to existing methods, e.g., coal and natural gas. But challenges do remain for widespread adoption of PV modules for power generation, including conversion efficiency, cost and reliability.

One significant challenge for conventional PV modules is long-term reliability, especially in climate extremes. Long-term reliability concerns are associated with both premature failures and unacceptable reductions in conversion efficiency. Conventional PV modules, including glass laminate modules, have been found to be susceptible to climate extremes, particularly dynamic climate conditions (e.g., hail strikes, heavy snow loading, wind gusts). At the same time, reinforcement for added long-term reliability often results in increased manufacturing cost and module weight. Further, as demand for PV modules increases, the need also increases for larger PV modules that may be more susceptible to extreme climate conditions given their increased size and weight.

Accordingly, there is a need for PV module configurations and design approaches which offer improved long-term reliability under exposure to various extreme climate conditions, preferably without sacrifice in cost and weight.

### SUMMARY

According to an aspect of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer is at least three times thinner than the inner glass layer. Further, the module exhibits a failure probability (P_{f}) of less than 15% upon exposure to an ice ball having a 1 inch diameter with an impact energy of 5 Joules according to the IEC 61215 & ASTM E1038 Hail Test.

According to another aspect of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer has a thickness of from 100 to 600 μm and the inner glass layer has a thickness of from 2.1 to 5 mm. Further, the polymeric encapsulant has an elastic modulus of from 100 MPa to 1000 MPa and a thickness of from 0.2 to 0.5 mm.

According to a further aspect of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer has a thickness of from 100 to 600 μm and the inner glass layer has a thickness of from 2.1 to 5 mm. Further, the polymeric encapsulant has an elastic modulus of from 0.1 MPa to 10 MPa and a thickness of from 0.01 to 0.2 mm.

Each of the foregoing PV modules and variants consistent with their concepts can offer improved long-term module reliability in the face of extreme climate conditions and in a manner not likely to increase cost and module weight.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a cross-sectional side view of a photovoltaic module, according to one or more embodiments described herein;

FIG. 1A is a cross-sectional side view of a photovoltaic module, according to one or more embodiments described herein;

FIG. 1B is a cross-sectional side view of a photovoltaic module, according to one or more embodiments described herein;

FIG. 2A is a cross-sectional side view of a photovoltaic module, according to one or more embodiments of the disclosure;

FIGS. 2B-2F are plots of failure probability as a function of ice ball impact energy, as generated through modeling of the photovoltaic module configuration of FIG. 2A with various permutations being subjected to an IEC 61215 & ASTM E1038 Hail Test, according to one or more embodiments described herein;

FIG. 3 is a plot of failure probability as a function of ice ball impact energy, as generated through modeling of a photovoltaic module configuration being subjected to an IEC 61215 & ASTM E1038 Hail Test, according to one or more embodiments described herein;

FIG. 4 is a plot of failure probability as a function of ice ball impact energy, as generated through modeling of a photovoltaic module configuration being subjected to an IEC 61215 & ASTM E1038 Hail Test, according to one or more embodiments described herein; and

FIG. 5 is a plot of failure probability as a function of ice ball impact energy, as generated through modeling of a photovoltaic module configuration being subjected to an IEC 61215 & ASTM E1038 Hail Test, according to one or more embodiments described herein.

### DETAILED DESCRIPTION

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example “up,” “down,” “right,” “left,” “front,” “back,” “top,” “bottom”—are made only with reference to the figures as drawn and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. Thus, for example, reference to a “component” includes aspects having two or more such components, unless the context clearly indicates otherwise.

As used herein, the term “dispose” includes coating, depositing, and/or forming a material onto a surface using any known or to be developed method in the art. The disposed material may constitute a layer, as defined herein. As used herein, the phrase “disposed on” includes forming a material onto a surface such that the material is in direct contact with the surface and embodiments where the material is formed on a surface with one or more intervening material(s) disposed between the material and the surface. The intervening material(s) may constitute a layer, as defined herein.

As used herein, the term “strengthened substrate” refers to a substrate that has been chemically strengthened, for example through ion-exchange of larger ions for smaller ions in the surface of the substrate. However, other strengthening methods known in the art, such as thermal tempering, or utilizing a mismatch of the coefficient of thermal expansion between portions of the substrate to create compressive stress and central tension regions, may be utilized to form strengthened substrates.

As used herein, the “IEC 61215 & ASTM E1038 Hail Test” is conducted according to the IEC 61215 & ASTM E1038 test protocols. In particular, the IEC 61215 & ASTM E1038 Hail Test is conducted according to the following protocols: IEC 61215-1:2021 Terrestrial photovoltaic (PV) modules—Design qualification and type approval—Part I: Test requirements; IEC 61215-1-2: 2021 Terrestrial photovoltaic (PV) modules—Design qualification and type approval—Part 1-2: Special requirements for testing of thin-film Cadmium Telluride (CdTe) based photovoltaic (PV) modules; and ASTM E1038-10:2015 Standard Test Method for Determining Resistance of Photovoltaic Modules to Hail by Impact with Propelled Ice Balls. In addition, the IEC 61215 & ASTM E1038 Hail Test is conducted with two modifications to the foregoing protocols, including the use of a test sample having dimensions of 398 mm×635 mm and impacting each test sample at one location on the glass surface of the PV module test sample with ice balls in a stair-step approach until visible cracks become apparent (i.e., cracks are visible with no magnification). Accordingly, as used herein, “failure” and “failure probability (P_{f})” are defined at a test condition (e.g., an ice ball with a 25 mm diameter (7.53 g) striking the sample at 23 m/s, corresponding to 2 Joules) in which test samples exhibit visible cracks.

Generally, the disclosure is directed to photovoltaic (PV) and solar modules that offer improved long-term reliability under exposure to various extreme climate conditions, likely without sacrifice in module cost and weight. The PV modules of this disclosure are asymmetric glass laminates that employ conventional PV structures and utilize a polymeric encapsulant. The laminates are asymmetric in the sense that the outermost glass layer (i.e., the side of the module exposed to incident solar radiation) is thinner, and often substantially thinner, than the innermost glass layer. Further, these asymmetric PV modules may further employ a particularly configured polymeric encapsulant, e.g., with a low elastic modulus and physical thickness or high in elastic modulus and thickness. In addition, these PV modules are expected to exhibit high reliability in various extreme climate conditions, including hail strikes, heavy snow loading and substantial wind events. Ultimately, these PV and solar modules can be employed in various utility, residential and commercial power-generation applications.

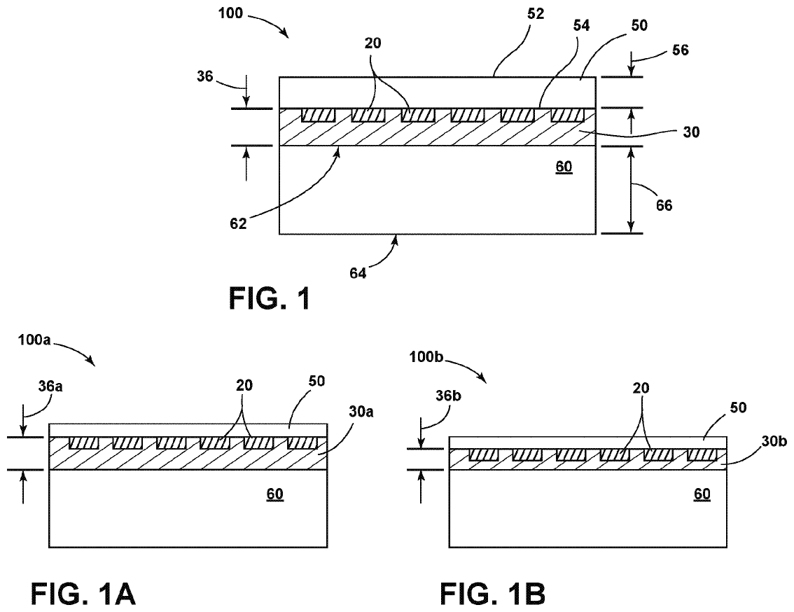

Reference will now be made in detail to various embodiments of photovoltaic (PV) modules, examples of which are illustrated in the accompanying drawings. Referring to FIG. 1, an exemplary PV module 100 can include: an outer glass layer 50; an inner glass layer 60; a plurality of photovoltaic (PV) structures 20 disposed on the outer glass layer 50; and a polymeric encapsulant 30 disposed over the plurality of PV structures 20 and between the inner glass layer 60 and outer glass layer 50. The outer glass layer 50 can define an outer primary surface 52 and an inner primary surface 54 opposing the outer primary surface 52, along with a thickness 56. Similarly, the inner glass layer 60 can define an outer primary surface 62 and an inner primary surface 64 opposing the outer primary surface 62, along with a thickness 66.

In this configuration of the PV module 100 depicted in FIG. 1, solar radiation is incident on the outer primary surface 52 of the outer glass layer 50 and is converted to power (e.g., electricity) by the plurality of PV structures 20. In embodiments, the plurality of PV structures 20 are disposed in close proximity to, or in contact with, the inner primary surface 54 of the outer glass layer 50. The polymeric encapsulant 30, as depicted in FIG. 1, resides between the outer glass layer 50 and inner glass layer 60 and can be configured to both encapsulate the plurality of PV structures 20 and adhere the outer and inner glass layers 50, 60. Further, the polymeric encapsulant 30 can serve to hermetically seal the plurality of PV structures 20 from the outside environment. Further, the polymeric encapsulant 30 can encapsulate the plurality of PV structures 20 such that the PV structures 20 are isolated from the inner glass layer 60 (e.g., electrically, from solid state diffusion of alkali metals in the glass composition, etc.).

With regard again to the PV module 100 depicted in exemplary form in FIG. 1, various photovoltaic structures are suitable for use in the plurality of PV structures 20 employed in the module 100. According to some embodiments, the PV structures 20 can be presented in a variety of forms including, but not limited to, wafered-Si, for example, crystalline silicon, macrocrystalline silicon, microcrystalline silicon, or combinations thereof. In some implementations, for example, each PV structure 20 can be one of a CdTe, amorphous silicon (a-Si), polysilicon (p-Si), CuIn/GaSe (CIGS), organic small-molecule, organic polymer, and perovskite (ABX₃) thin-film PV structure. Further, according to some embodiments of the PV module 100, the plurality of PV structures 20 are formed as thin-film structures in the form of a layer having a thickness of less than 10 μm.

Referring again to the photovoltaic (PV) module 100 depicted in exemplary form in FIG. 1, embodiments of the module are such that it is asymmetric, with a thinner outer glass layer 50 than the inner glass layer 60. That is, the thicknesses 56 and 66 of the outer and inner glass layers 50, 60 generally differ from one another. In some implementations, the thickness 56 of the outer glass layer 50 is at least three times thinner than the thickness 66 of the inner glass layer 60. According to some embodiments, the outer glass layer 50 is thinner than the inner glass layer 60 by a factor of at least 2, 2.5, 3, 3.5, 4, 4.5, 5, or even more. For example, the thickness 56 of the outer glass layer 50 can be a factor of about 2, 2.25, 2.5, 2.75, 3, 3.5, 4, 4.5, 5, 6, 7, 8, 9, or 10 thinner than the thickness 66 of the inner glass layer 60.

According to some implementations of the PV module 100 depicted in FIG. 1, the thickness 56 of the outer glass layer 50 can range from 50 to 1000 μm, 100 to 750 μm, 100 to 600 μm, 150 to 500 μm, and all thickness sub-ranges between the foregoing ranges. For example, the thickness 56 of the outer glass layer 50 can be about 50, 100, 150, 200, 250, 300, 350, 400, 450, 500, 600, 700, 800, 900, 1000 μm, and all thickness values between these thicknesses.

According to some embodiments of the PV module 100 depicted in FIG. 1, the thickness 66 of the inner glass layer 60 can range from about 1.5 to 7.5 mm, 1.5 to 6 mm, 2 mm to 6 mm, 2.1 to 5 mm, 2.5 to 5 mm, and all thickness sub-ranges between the foregoing ranges. For example, the thickness 66 of the inner glass layer can be about 1.5, 1.75, 2.0, 2.1, 2.2, 2.3, 2.4, 2.5, 2.75, 3, 3.5, 4, 4.5, 5, 5.5, 6, 6.5, 7, 7.5 mm, and all thickness values between the foregoing thickness values.

Referring again to the PV module 100 depicted in FIG. 1, its outer glass layer 50, as noted earlier, is typically thinner than the inner glass layer 60. In some implementations, the composition of outer glass layer 50 is selected from any of the various glass compositions classified by those skilled in the field of this disclosure as Ultra-Thin Flexible (UTF) glass (e.g., Corning® Willow® glass). Such glass compositions can be suitable to ensure that module 100 remains substantially failure-free (<1%) upon bending with a thickness 56 of the outer glass layer 50 ranging from 50 to 1000 μm. In some implementations, the composition of the outer glass layer 50 is substantially alkali metal-free, e.g., to further enhance device efficiency and reliability. In other embodiments, the composition of the outer glass layer 50 is selected with sufficient levels of alkali metal(s) (e.g., Na⁺, K⁺, Li⁺ ions, etc.) to facilitate strengthening through ion-exchange (IOX) processing, as detailed below.

Still referring to the PV module 100 depicted in FIG. 1, its inner glass layer 60, as noted earlier, is typically thicker than the outer glass layer 50. In some implementations, the composition of the inner glass layer 60 can comprise a soda-lime glass (SLG) composition, other glass compositions with high optical transmittance and strength, e.g., tempered low-Fe SLG glass, or any other structural glass composition suitable for lamination to a thinner outer glass layer, e.g., an outer glass layer 50 with a UTF composition. Further, in some implementations, the composition of the inner glass layer 60 is selected to facilitate the development of a compressive stress region through an IOX process, e.g., a glass composition with sufficient levels of alkali metal(s).

The outer and inner glass layers 50, 60 of the PV module 100 depicted in FIG. 1 may be provided using a variety of different processes. For instance, the various forming methods can include float glass processes and down-draw processes such as fusion draw and slot draw.

Referring again to the PV module 100 depicted in FIG. 1, the outer and inner glass layers 50, 60 are, in some embodiments, selected with compositions(s) such that they have the same or substantially the same coefficient of thermal expansion (CTE). In some embodiments, each of the outer and inner glass layers 50, 60 possess a CTE of less than about 10, 7.5, or even 5 ppm/° C. For example, each of the outer and inner glass layers 50, 60 can exhibit a CTE of 10, 9, 8, 7, 6, 5, 4, 3, 2, 1 ppm/° C., or other CTE value between the foregoing levels.

Once formed, either or both of the outer and inner glass layers 50, 60 may be strengthened to form a strengthened substrate. Where the outer and/or inner glass layers 50, 60 are chemically strengthened by an ion exchange process, the ions in the surface layer of the substrate are replaced by—or exchanged with—larger ions having the same valence or oxidation state. Ion exchange processes are typically carried out by immersing a substrate in a molten salt bath containing the larger ions to be exchanged with the smaller ions in the glass layer(s). It will be appreciated by those skilled in the art that parameters for the ion exchange process, including, but not limited to, bath composition and temperature, immersion time, the number of immersions of the glass layer(s) in a salt bath (or baths), use of multiple salt baths, and additional steps such as annealing, washing, and the like, are generally determined by the composition of the substrate and the desired compressive stress (CS), depth of compressive stress layer (or depth of layer DOL, or depth of compression DOC) of the substrate that result from the strengthening operation. By way of example, ion exchange of alkali metal-containing glass layer(s) may be achieved by immersion in at least one molten bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 40 hours. However, temperatures and immersion times different from those described above may also be used.

In addition, non-limiting examples of ion exchange processes in which glass layer(s) 50, 60 are immersed in multiple ion exchange baths, with washing and/or annealing steps between immersions, are described in U.S. patent application Ser. No. 12/500,650, filed Jul. 10, 2009, by Douglas C. Allan et al., entitled “Glass with Compressive Surface for Consumer Applications,” and claiming priority from U.S. Provisional Patent Application No. 61/079,995, filed Jul. 11, 2008, in which glass layer(s) are strengthened by immersion in multiple, successive, ion exchange treatments in salt baths of different concentrations; and U.S. Pat. No. 8,312,739, by Christopher M. Lee et al., issued on Nov. 20, 2012, and entitled “Dual Stage Ion Exchange for Chemical Strengthening of Glass,” and claiming priority from U.S. Provisional Patent Application No. 61/084,398, filed Jul. 29, 2008, in which glass layer(s) are strengthened by ion exchange in a first bath diluted with an effluent ion, followed by immersion in a second bath having a smaller concentration of the effluent ion than the first bath. The contents of U.S. patent application Ser. No. 12/500,650 and U.S. Pat. No. 8,312,739 are incorporated herein by reference in their entirety.

The degree of chemical strengthening achieved by ion exchange may be quantified based on the parameters of central tension (CT), surface CS, and depth of compression (DOC). Compressive stress (including surface CS) is measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety. Maximum CT values are measured using a scattered light polariscope (SCALP) technique known in the art. As used herein, DOC means the depth at which the stress in the chemically strengthened alkali aluminosilicate glass layer(s) described herein changes from compressive to tensile. DOC may be measured by FSM or SCALP depending on the ion exchange treatment. Where the stress in the glass layer(s) is generated by exchanging potassium ions into the glass layer(s), FSM is used to measure DOC. Where the stress is generated by exchanging sodium ions into the glass layer(s), SCALP is used to measure DOC. Where the stress in the glass layer(s) is generated by exchanging both potassium and sodium ions into the glass, the DOC is measured by SCALP, since it is believed the exchange depth of sodium indicates the DOC and the exchange depth of potassium ions indicates a change in the magnitude of the compressive stress (but not the change in stress from compressive to tensile); the exchange depth of potassium ions in such glass layer(s) is measured by FSM.

In one embodiment, either or both of the outer and inner glass layers 50, 60 can have a surface CS of 250 MPa or greater, 300 MPa or greater, e.g., 400 MPa or greater, 450 MPa or greater, 500 MPa or greater, 550 MPa or greater, 600 MPa or greater, 650 MPa or greater, 700 MPa or greater, 750 MPa or greater or 800 MPa or greater. The strengthened substrate may have a DOC of 10 μm or greater, 15 μm or greater, 20 μm or greater (e.g., 25 μm, 30 μm, 35 μm, 40 μm, 45 μm, 50 μm or greater) and/or a CT of 10 MPa or greater, 20 MPa or greater, 30 MPa or greater, 40 MPa or greater (e.g., 42 MPa, 45 MPa, or 50 MPa or greater) but less than 100 MPa (e.g., 95, 90, 85, 80, 75, 70, 65, 60, 55 MPa or less). In one or more specific embodiments, the strengthened substrate (i.e., outer and/or inner glass layers 50, 60) has one or more of the following: a surface CS greater than 500 MPa, a DOC greater than 15 μm, and a CT greater than 18 MPa. In some implementations, the compressive stress region of either or both of the outer and inner glass layers 50, 60 may be at least 20% of its thickness 56, 66 and exhibit a CS of at least 800 MPa.

Example glasses that may be used for the outer and inner glass layers 50, 60, including those that are processed to be a ‘strengthened substrate,’ may include alkali aluminosilicate glass compositions or alkali aluminoborosilicate glass compositions, though other glass compositions are contemplated. Such glass compositions are capable of being chemically strengthened by an ion exchange process. One example glass composition comprises SiO₂, B₂O₃ and Na₂O, where (SiO₂+B₂O₃)≥66 mol. %, and Na₂O≥9 mol. %. In an embodiment, the glass composition includes at least 6 wt. % aluminum oxide. In a further embodiment, the substrate includes a glass composition with one or more alkaline earth oxides, such that a content of alkaline earth oxides is at least 5 wt. %. Suitable glass compositions, in some embodiments, further comprise at least one of K₂O, MgO, and CaO. In a particular embodiment, the glass compositions used in either or both of the outer and inner glass layers 50, 60 can comprise 61-75 mol. % SiO₂; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

A further example glass composition suitable for either or both of the outer and inner glass layers 50, 60 comprises: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm Sb₂O₃; where 12 mol. %≤(Li₂O+Na₂O+K₂O)≤20 mol. % and 0 mol. %≤(MgO+CaO)≤10 mol. %. A still further example glass composition suitable for either or both of the outer and inner glass layers 50, 60 comprises: 63.5-66.5 mol % SiO₂; 8-12 mol. % Al₂O₃; 0-3 mol % B₂O₃; 0-5 mol. % Li₂O; 8-18 mol. % Na₂O; 0-5 mol. % K₂O; 1-7 mol. % MgO; 0-2.5 mol. % CaO; 0-3 mol. % ZrO₂; 0.05-0.25 mol. % SnO₂; 0.05-0.5 mol. % CeO₂; less than 50 ppm As₂O₃; and less than 50 ppm Sb₂O₃; where 14 mol. %≤(Li₂O+Na₂O+K₂O)≤18 mol. % and 2 mol. %≤(MgO+CaO)≤7 mol. %.

In a particular embodiment, an alkali aluminosilicate glass composition suitable for either or both of the outer and inner glass layers 50, 60 comprises alumina, at least one alkali metal and, in some embodiments, greater than 50 mol. % SiO₂, in other embodiments at least 58 mol. % SiO₂, and in still other embodiments at least 60 mol. % SiO₂, wherein the ratio (Al₂O₃+B₂O₃)/Σmodifiers (i.e., sum of modifiers) is greater than 1, where in the ratio the components are expressed in mol. % and the modifiers are alkali metal oxides. This glass composition, in particular embodiments, comprises: 58-72 mol. % SiO₂; 9-17 mol. % Al₂O₃; 2-12 mol. % B₂O₃; 8-16 mol. % Na₂O; and 0-4 mol. % K₂O, wherein the ratio (Al₂O₃+B₂O₃)/Σmodifiers (i.e., sum of modifiers) is greater than 1.

In still another embodiment, either or both of the outer and inner glass layers 50, 60 may include an alkali aluminosilicate glass composition comprising: 64-68 mol. % SiO₂; 12-16 mol. % Na₂O; 8-12 mol. % Al₂O₃; 0-3 mol. % B₂O₃; 2-5 mol. % K₂O; 4-6 mol. % MgO; and 0-5 mol. % CaO, wherein: 66 mol. %≤SiO₂+B₂O₃+CaO≤69 mol. %; Na₂O+K₂O+B₂O₃+MgO+CaO+SrO>10 mol. %; 5 mol. %≤MgO+CaO+SrO≤8 mol %; (Na₂O+B₂O₃)—Al₂O₃≤2 mol. %; 2 mol. %≤Na₂O—Al₂O₃≤6 mol. %; and 4 mol. %≤(Na₂O+K₂O)—Al₂O₃≤10 mol. %.

Referring again to the PV module 100 depicted in FIG. 1, the module includes a polymeric encapsulant 30 that resides between the outer glass layer 50 and inner glass layer 60 and is disposed over the plurality of PV structures 20. In embodiments, the polymeric encapsulant is selected to adhere the outer and inner glass layers 50, 60 together with a high peel strength as measured between them and, preferably, with a low water vapor transmission rate. Suitable CTE levels for the polymeric encapsulant 30 can range from 50 to 200 ppm/° C., 75 to 175 ppm/° C., and all CTE levels in the foregoing ranges. Suitable polymeric encapsulant 30 materials include, but are not limited to, silicone, ionomer (e.g., SentryGlas® made by Kuraray America), thermoplastic polyolefin (TPO), polyolefin (PO), polyvinyl butyral (PVB), thermoplastic polyurethane (TPU), and ethylene vinyl acetate (EVA) adhesives.

Still referring to the PV module 100 depicted in FIG. 1, the polymeric encapsulant 30 can be selected such that it has a particular elastic modulus within a fairly wide range, e.g., from 0.1 to 1000 MPa or a narrower range, e.g., from 0.1 to 10 MPa or 100 to 1000 MPa. For example, the polymeric encapsulant 30 can be selected (e.g., through processing and/or material selection) such that it exhibits an elastic modulus of 0.1, 1, 5, 10, 50, 100, 200, 300, 400, 500, 750 or even as high as 1000 MPa, and all elastic modulus values between the foregoing levels.

Referring again to the PV module 100 depicted in FIG. 1, the polymeric encapsulant 30 can also be selected with a thickness 36. In some implementations, the thickness 36 of the encapsulant 30 ranges from 0.01 mm to 0.5 mm, 0.05 mm to 0.5 mm, or a narrower range, e.g., from 0.2 to 0.5 mm, 0.05 to 0.2 mm, or 0.01 to 0.2 mm. For example, the polymeric encapsulant 30 can be selected with a thickness 36 of 0.01, 0.025, 0.05, 0.1, 0.15, 0.2, 0.25, 0.3, 0.35, 0.4, 0.45, 0.5 mm, and all thickness values between the foregoing levels. In some implementations, the polymeric encapsulant 30 is a silicone applied in liquid form with a thickness 36 of less than 0.05 mm, e.g., 0.005 mm, 0.01 mm, 0.025 mm, 0.04 mm, etc.

Without being bound by theory, the reliability of the PV module 100 depicted in FIG. 1 upon exposure to extreme climate conditions (e.g., hail strikes, heavy snow and/or wind gusts), and the reliability of the other PV modules of the disclosure, can surprisingly be enhanced through the careful selection of the stiffness (i.e., elastic modulus) and thickness 36 of the polymeric encapsulant 30, particularly in view of the material properties and dimensions of the outer and inner glass layers 50, 60. For example, the use of particularly stiff and thick polymeric encapsulants 30 in the PV modules 100a (see FIG. 1A and corresponding description below) can result in enhanced long-term module reliability upon exposure to extreme climate conditions. As another example, the use of particularly soft and thin polymeric encapsulants 30 in the PV modules 100b (see FIG. 1B and corresponding description below) can result in enhanced long-term module reliability upon exposure to extreme climate conditions.

Referring now to FIG. 1A, a PV module 100a is depicted with a stiff and thick polymeric encapsulant 30a. Unless otherwise noted, the PV module 100a depicted in FIG. 1A is materially the same as the PV module 100 depicted in FIG. 1, with common elements having the same or materially the same structures and functions. Notably, the PV module 100a depicted in FIG. 1A includes an optimized polymeric encapsulant 30a which is both stiff and thick. In some implementations of the PV module 100a, the polymeric encapsulant 30a has an elastic modulus of from 100 MPa to 1000 MPa, and a thickness 36a from 0.2 to 0.5 mm. For example, the polymeric encapsulant 30a can have an elastic modulus of 100, 200, 300, 400, 500, 600, 700, 800, 900, or 1000 MPa and a thickness 36a of 0.2, 0.25, 0.3, 0.35, 0.4, 0.45, or 0.5 mm, and all modulus and thickness values between the foregoing levels. Further, in these implementations, the polymeric encapsulant 30a can be selected from the group consisting of thermoplastic polyolefin (TPO), ionomer, (e.g., SentryGlas® made by Kuraray America), polyolefin (PO) and polyvinyl butyral (PVB) adhesives.

Referring now to FIG. 1B, a PV module 100b is depicted with a soft and thin polymeric encapsulant 30b. Unless otherwise noted, the PV module 100b depicted in FIG. 1B is materially the same as the PV module 100 depicted in FIG. 1, with common elements having the same or materially the same structures and functions. Notably, the PV module 100b depicted in FIG. 1B includes an optimized polymeric encapsulant 30b which is both soft and thin. In some implementations of the PV module 100b, the polymeric encapsulant 30b has an elastic modulus of from 0.1 MPa to 10 MPa, and a thickness 36b from 0.05 to 0.2 mm. For example, the polymeric encapsulant 30b can have an elastic modulus of 0.1, 0.25, 0.5, 0.75, 1, 2, 3, 4, 5, 7.5, or 10 MPa and a thickness 36b of 0.05, 0.075, 0.1, 0.125, 0.15, 0.175, or 0.2 mm, and all modulus and thickness values between the foregoing levels. Further, in these implementations, the polymeric encapsulant 30b can be selected from the group consisting of silicone, thermoplastic polyurethane (TPU), and ethylene vinyl acetate (EVA) adhesives.

Referring again to the PV modules 100-100b depicted in FIGS. 1-1B, each of these modules is surprisingly configured to exhibit enhanced reliability upon exposure to extreme climate conditions (e.g., hail strikes, heavy snow evolutions, wind gusts, sustained high-level winds, etc.), typically as simulated through testing. Without being bound by theory, the selection of the material and thickness 36 of the polymeric encapsulant 30, based in part on the properties and dimensions of the outer and inner glass layers 50, 60, can drive these module-level performance attributes, which can exceed those of conventional PV modules.

In some implementations of the modules 100-100b depicted in FIGS. 1-1B, for example, the module can exhibit a failure probability (P_{f}) of less than 15% upon exposure to an ice ball having a 1 inch diameter with an impact energy of 5 Joules (or less) according to the IEC 61215 & ASTM E1038 Hail Test. These failure probabilities can be assessed by examination of either or both of the primary surfaces 52, 54 of the outer glass layer 50. Embodiments of these modules exhibit a failure probability of less than 15% for such ice balls applied with an impact energy of 5 Joules or less, e.g., 4.5 J, 4 J, 3.5 J, etc.

According to some embodiments of the module 100-100b depicted in FIGS. 1-1B, these modules can be configured to exhibit a failure probability (P_{f}) of less than 2% upon exposure to an ice ball having a 1 inch diameter with an impact energy of 5 Joules according to the IEC 61215 & ASTM E1038 Hail Test. Thus, embodiments of these modules exhibit a failure probability of less than 2% for such ice balls applied with an impact energy of 5 Joules or less, e.g., 4.5 J, 4 J, 3.5 J, etc.

According to some implementations, the modules 100-100b can also exhibits no failures upon exposure to an ice ball having a 1.75 inch diameter with a velocity of 30 m/s according to the IEC 61215 & ASTM E1038 Hail Test. For example, such modules 100-100b can exhibit no failures upon exposure to 1.75 inch ice balls applied with a velocity of 30 m/s or less, e.g., 27.5 m/s, 25 m/s, 22.5 m/s, 20 m/s, etc.

Referring again to the modules 100-100b depicted in FIGS. 1-1B, the modules can be fabricated and laminated according to conventional processes understood by those skilled in the field of the disclosure. In some embodiments, the plurality of PV structures 20 can be deposited and/or printed on the outer glass layer 50 (e.g., on inner primary surface 54) using roll-to-roll (R2R) processing. R2R processing offers the opportunity to significantly reduce module production costs due to increased line speeds. While some polymeric encapsulant materials (e.g., EVA) are generally not thought to be compatible with R2R processes, softer polymeric encapsulant materials as envisioned in this disclosure (see, e.g., PV module 100b depicted in FIG. 1B and described above) could be applied downstream of the formation of the plurality of PV structures 20 as part of an R2R process and then laminated to the inner glass layer 60 using a roll-to-sheet (R2S) nip lamination approach, as also understood by those skilled in the field of the disclosure. In other words, aspects of the PV modules of the disclosure, e.g., PV modules 100b, can combine an optimized polymeric encapsulant 30 with a thickness 36 and low elastic modulus (i.e., for long-term module reliability) with a R2S lamination method that could offer the advantage of a durable PV module, as-produced at low cost.

### EXAMPLES

Various embodiments of the PV modules of the disclosure will be further clarified by the following modeled examples. In these examples, hail strike failure probability (P_{f}) calculations were performed on PV modules with the following construction: an outer glass layer having a thickness of 100 μm and Corning® Willow® composition; a polymeric encapsulant having a thickness from 0.1 to 0.5 mm and of a material as noted in the particular examples; and an inner glass layer having a thickness from 2.1 to 5 mm and a soda lime glass (SLG) composition.

The failure probability (P_{f}) modeling in these examples was conducted to simulate striking the outer glass layer of the PV modules with 1″ and 1.75″ diameter ice balls using the IEC 61215 & ASTM E1038 Hail Test. Each PV module was assumed to have a width of 400 mm and a length of 600 mm. Further, the scaling strength levels of the outer glass layer and the inner glass layer were calculated based on the approaches set forth in: Joshi, D., Kittleson, A. P., & Harris, J. T., “Probability of failure and weibull size-scaling parameters for thin glass subjected to two-point bending”, Journal of the European Ceramic Society, 2022, 42(16), 7609-7619 and ASTM C1683, respectively. Further, the salient portions of the foregoing references are hereby incorporated in this disclosure. In the modeling, the ice ball was considered to be a deformable solid in a strain rate dependent plasticity model implemented in ABAQUS software. The strain rate dependent plasticity model is as set forth in Tippmann, J. D., “Development of a strain rate sensitive ice material model for hail ice impact simulation”, 2011, University of California, San Diego, the salient portions of which are hereby incorporated by reference in this disclosure. Further, each PV module was considered in the modeling to be supported on its edges and the impact strike was assumed to be at the center of the PV module at ambient temperature. The border (width 1¾″) of the PV laminate model geometry was constrained to move in the out-of-plane direction while allowing free motion in other directions. This boundary condition simulates the ‘framed support structure’ in the actual test that was performed. A quarter-symmetry model was employed to reduce the simulation run-time. The plurality of PV structures in the PV module was assumed to be extremely thin with a relatively low contribution to the overall stiffness of the PV module and, therefore, it was not included in the model.

### Example 1

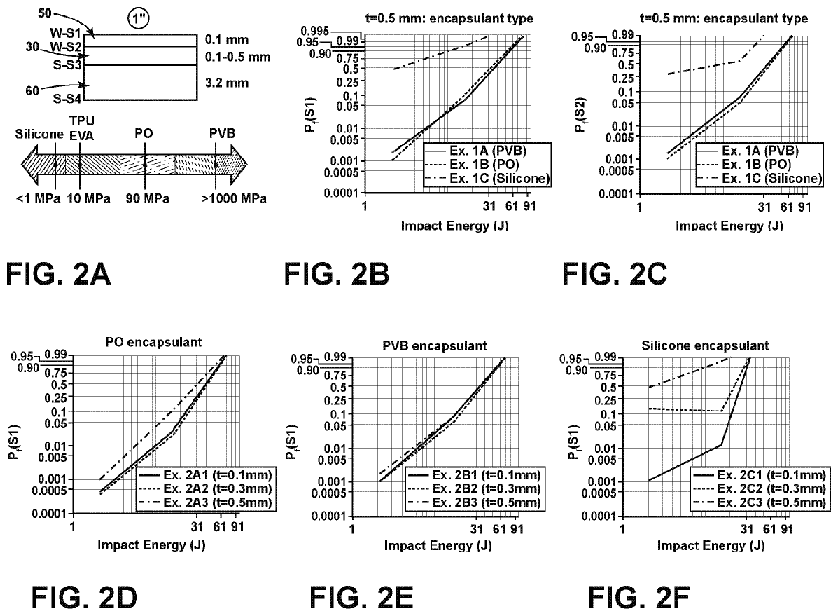

In this example, PV modules as depicted in FIG. 2A were subjected to hail strike modeling according to the IEC 61215 & ASTM E1038 Hail Test. The outer glass layer and inner glass layer were assumed to have a constant thickness of 0.1 mm and 3.2 mm, respectively. The thickness of the polymeric encapsulant was also held constant at a thickness of 0.5 mm, and three materials were investigated: PVB (Ex. 1A); PO (Ex. 1B); and silicone (Ex. 1C).

Referring now to FIGS. 2B and 2C, plots are provided of failure probability (P_{f}) as a function of ice ball impact energy (Joules), as generated through modeling of the photovoltaic module configuration of FIG. 2A with the various PV module permutations having different polymeric encapsulant materials, as designated Exs. 1A-1C. Further, FIGS. 2B and 2C are similar with failure probabilities calculated at the outer primary surface and inner primary surface of the outer glass layer, S1 and S2, respectively. Note that the inner primary surface, S2, is in contact with the polymeric encapsulant. As is evident from both FIGS. 2B and 2C, failure probabilities in these PV module configurations were substantially lower for those samples employing the higher modulus polymeric encapsulant materials, i.e., PO (Ex. 1B) and PVB (Ex. 1C).

### Example 2

In this example, PV modules as depicted in FIG. 2A were subjected to hail strike modeling according to the IEC 61215 & ASTM E1038 Hail Test. The outer glass layer and inner glass layer were assumed to have a constant thickness of 0.1 mm and 3.2 mm, respectively. The thickness of the polymeric encapsulant in the PV modules was set at 0.1 mm, 0.3 mm, and 0.5 mm, and three materials were investigated: PO (Exs. 2A1-2A3); PVB (Exs. 2B1-2B3); and silicone (Exs. 2C1-2C3).

Referring now to FIGS. 2D-2F, plots are provided of failure probability (P_{f}) as a function of ice ball impact energy (Joules), as generated through modeling of the photovoltaic module configuration of FIG. 2A with the various PV module permutations having different polymeric encapsulant materials and thickness. FIG. 2D depicts modeling of PV modules with a PO polymeric encapsulant having thicknesses of 0.1, 0.3 and 0.5 mm (Exs. 2A1-2A3); FIG. 2E depicts modeling of PV modules with a PVB polymeric encapsulant having thicknesses of 0.1, 0.3 and 0.5 mm (Exs. 2B1-2B3), and FIG. 2F depicts modeling of PV modules with a silicone polymeric encapsulant having thicknesses of 0.1, 0.3 and 0.5 mm (Exs. 2C1-2C3).

As is evident from FIGS. 2D and 2E, the PV modules employing PO and PVB encapsulants (as having an elastic modulus of 90 MPa and >1000 MPa, respectively) performed well with low failure probabilities at all encapsulant thicknesses, i.e., from 0.1 to 0.5 mm. With regard to FIG. 2F, the PV modules employing the silicone polymeric encapsulants performed best with the lowest failure probabilities for encapsulants having the lowest thickness, 0.1 mm, and slightly worse for encapsulants having a moderate thickness of 0.3 mm.

### Example 3

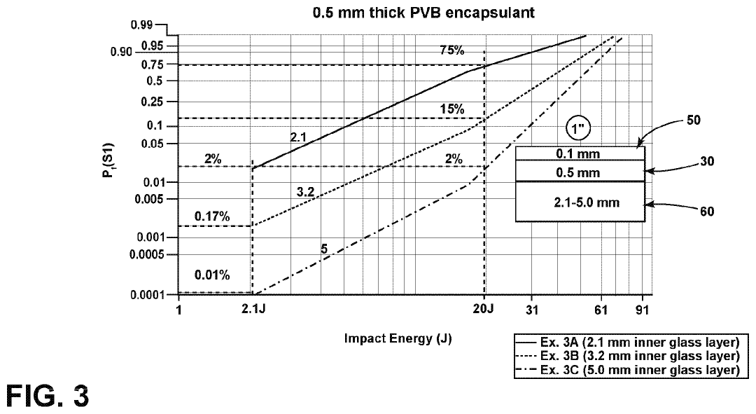

In this example, PV modules as depicted in FIG. 3 were subjected to hail strike modeling according to the IEC 61215 & ASTM E1038 Hail Test. The outer glass layer and polymeric encapsulant were assumed to have a constant thickness of 0.1 mm and 0.5 mm, respectively. Further, the polymeric encapsulant was assumed to be PVB material. In addition, the inner glass layer in the PV module was modeled with a varying thickness, 2.1 mm, 3.2 mm and 5.0 mm (Exs. 3A-3C, respectively).

Referring now to FIG. 3, a plot is provided of failure probability (P_{f}) as a function of ice ball impact energy (Joules), as generated through modeling of the photovoltaic module configuration of this figure with the various PV module permutations having different inner glass layer thickness values. As is evident from this figure, the PV modules with the thickest inner glass layer, 5.0 mm (Ex. 3C), exhibited the best performance with lowest failure probabilities. The PV modules with moderately thick inner glass layers, 3.2 mm (Ex. 3B), exhibited good performance with slightly higher failure probabilities.

### Example 4

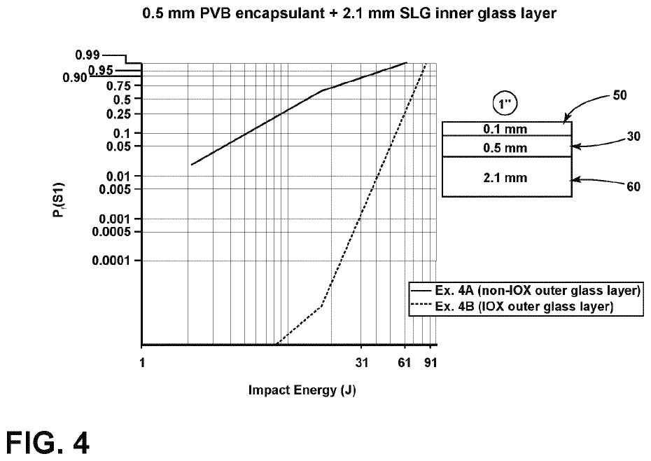

In this example, PV modules as depicted in FIG. 4 were subjected to hail strike modeling according to the IEC 61215 & ASTM E1038 Hail Test. The outer glass layer, polymeric encapsulant, and inner glass layer were held at constant thicknesses: 0.1 mm, 0.5 mm, and 2.1 mm, respectively. Further, two outer glass layer conditions were investigated, with and without an IOX-developed compressive stress region (Ex. 4A, non-IOX; and Ex. 4B, IOX). The inner glass layer, however, has an SLG composition that is not ion-exchange strengthened.

Referring now to FIG. 4, a plot is provided of failure probability (P_{f}) as a function of ice ball impact energy (Joules), as generated through modeling of the photovoltaic module configuration of this example with the various PV module permutations having different outer glass layer compressive stress conditions. As is evident from this figure, the PV modules with the IOX-developed compressive stress region in the outer glass layer (Ex. 4B) exhibited better performance from a failure probability standpoint than the PV modules without the IOX-developed compressive stress region in the outer glass layer (Ex. 4A).

### Example 5

In this example, PV modules were subjected to hail strike modeling according to the IEC 61215 & ASTM E1038 Hail Test. The outer glass layer, polymeric encapsulant, and inner glass layer were held at constant thicknesses: 0.1 mm, 0.5 mm, and 3.2 mm, respectively. Further, two ice strike conditions were evaluated, 1″ diameter ice balls (Ex. 5A) and 1.75″ diameter ice balls (Ex. 5B).

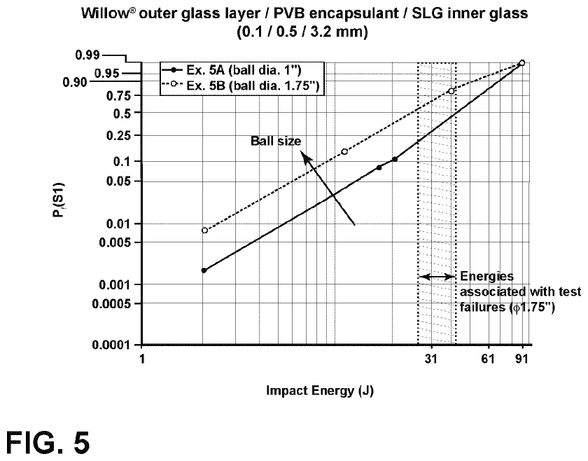

Referring now to FIG. 5, a plot is provided of failure probability (P_{f}) as a function of ice ball impact energy (Joules), as generated through modeling of the photovoltaic module configuration of this example with different ice strike conditions: 1″ and 1.75″ diameter ice balls (Exs. 5A and 5B). As is evident from this figure, the PV modules subjected to the smaller diameter ice balls (Ex. 5A) exhibited better performance from a failure probability standpoint than the PV modules subjected to the larger diameter ice balls (Ex. 5B).

### Example 6

In this example, PV modules were subjected to actual hail strike testing according to the IEC 61215 & ASTM E1038 Hail Test using a 1.75″ diameter ice ball. In these tests, the velocity of the ice ball (m/s) was recorded for the condition in which the particular PV module experienced a failure. In most of the tests, the ice ball was directed against the outer glass layer of the PV module, either at its center or at one of its corners. In some tests, however, the ice ball was directed against the inner glass layer to simulate an arrangement in which the PV module was reversed in its orientation relative to incident solar radiation.

In this example, the PV modules were configured as listed below in Table 1, and each PV module tested had a width of 400 mm and a length of 600 mm. In particular, the inner glass layer comprised an SLG glass composition and was set at two thicknesses, 5 and 3.2 mm. Further, the polymeric encapsulant used in these PV modules was as follows: PVB with a thickness of 0.38 mm, PVB with a thickness of 0.76 mm, and ionomer (SentryGlas®) with a thickness of 0.89 mm. Further, the outer glass layer employed in this testing had a Corning® Willow® glass composition and a thickness of 0.1 mm. In addition, none of the glass layers in these PV modules contained a compressive stress region as developed through an IOX process.

TABLE 1
Experimental Conditions of PV Module Hail Strike Testing

| SLG inner | | Polymeric | | | | | | |
|---|---|---|---|---|---|---|---|---|
| glass layer | Polymeric | encapsulant | | PV module breaking velocity (m/s) | | | | |
| thickness | encapsulant | thickness | Impact | Replicate 1 | | Modified | Replicate 2 | |
| (mm) | type | (mm) | side | Center | Corner | location | Center | Corner |
| 5 | PVB | 0.38 | Willow ® | >64 | >64 | Willow ® | x | >64 |
| | PVB | 0.38 | SLG | >64 | >64 | surface | >64 | xx |
| | PVB | 0.76 | Willow ® | 61 | 64 | | x | 61 |
| | PVB | 0.76 | SLG | >64 | >64 | | >64 | x |
| | Sentry Glas ® | 0.89 | Willow ® | 64 | 61 | | x | 58.2 |
| | Sentry Glas ® | 0.89 | SLG | >64 | >64 | | x | x |
| 3.2 | PVB | 0.38 | Willow ® | 34.1 | x | | | |
| | PVB | 0.38 | Willow ® | 43.8 | x | | | |

As is evident from Table 1, the samples with a relatively thin polymeric encapsulant (PVB at 0.38 mm thickness) and a thick SLG inner glass layer (5 mm) performed well in testing with breaking velocities in excess of 64 m/s. Other PV modules with slightly thicker polymer encapsulant materials (PVB at 0.76 mm thickness; and SentryGlas® at 0.89 mm) also performed well with breaking velocities in excess of 60 m/s. Further, some PV modules with a relatively thin SLG inner glass layer (3.2 mm) with a relatively thin polymeric encapsulant (PVB at 0.38 mm thickness) performed well with breaking velocities of more than 30 m/s, but not as well as the other samples.

The various features described in the specification may be combined in any and all combinations, for example, as listed in the following embodiments.

Embodiment 1. According to Embodiment 1 of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer is at least three times thinner than the inner glass layer. Further, the module exhibits a failure probability (P_{f}) of less than 15% upon exposure to an ice ball having a 1 inch diameter with an impact energy of 5 Joules according to the IEC 61215 & ASTM E1038 Hail Test.

Embodiment 2. According to Embodiment 2 of the disclosure, Embodiment 1 is provided, wherein the module exhibits a failure probability (P_{f}) of less than 2% upon exposure to an ice ball having a 1 inch diameter with an impact energy of 5 Joules according to the IEC 61215 & ASTM E1038 Hail Test.

Embodiment 3. According to Embodiment 3 of the disclosure, Embodiment 1 or Embodiment 2 is provided, wherein the module exhibits no failures upon exposure to an ice ball having a 1.75 inch diameter with a velocity of 30 m/s according to the IEC 61215 & ASTM E1038 Hail Test.

Embodiment 4. According to Embodiment 4 of the disclosure, any one of Embodiments 1-3 is provided, wherein the encapsulant comprises one or more adhesives selected from the group consisting of silicone, ionomer, thermoplastic polyolefin (TPO), polyolefin (PO), polyvinyl butyral (PVB), thermoplastic polyurethane (TPU), and ethylene vinyl acetate (EVA) adhesives.

Embodiment 5. According to Embodiment 5 of the disclosure, any one of Embodiments 1~4 is provided, wherein each of the glass layers exhibits a coefficient of thermal expansion (CTE) of less than 10 ppm/° C. and the polymeric encapsulant exhibits a CTE of 50 to 200 ppm/° C.

Embodiment 6. According to Embodiment 6 of the disclosure, any one of Embodiments 1-5 is provided, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

Embodiment 7. According to Embodiment 7 of the disclosure, any one of Embodiments 1-6 is provided, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.

Embodiment 8. According to Embodiment 8 of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer has a thickness of from 100 to 600 μm and the inner glass layer has a thickness of from 2.1 to 5 mm. Further, the polymeric encapsulant has an elastic modulus of from 100 MPa to 1000 MPa and a thickness of from 0.2 to 0.5 mm.

Embodiment 9. According to Embodiment 9 of the disclosure, Embodiment 8 is provided, wherein the module exhibits a failure probability (P_{f}) of less than 15% upon exposure to an ice ball having a 1 inch diameter with an impact energy of 5 Joules according to the IEC 61215 & ASTM E1038 Hail Test.

Embodiment 10. According to Embodiment 10 of the disclosure, Embodiment 8 is provided, wherein the module exhibits a failure probability (P_{f}) of less than 2% upon exposure to an ice ball having a 1 inch diameter with an impact energy of 5 Joules according to the IEC 61215 & ASTM E1038 Hail Test.

Embodiment 11. According to Embodiment 11 of the disclosure, any one of Embodiments 8-10 is provided, wherein the encapsulant comprises one or more adhesives selected from the group consisting of thermoplastic polyolefin (TPO), polyolefin (PO), ionomer, and polyvinyl butyral (PVB) adhesives.

Embodiment 12. According to Embodiment 12 of the disclosure, any one of Embodiments 8-11 is provided, wherein each of the glass layers exhibits a coefficient of thermal expansion (CTE) of less than 10 ppm/° C. and the polymeric encapsulant exhibits a CTE of 50 to 200 ppm/° C.

Embodiment 13. According to Embodiment 13 of the disclosure, any one of Embodiments 8-12 is provided, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

Embodiment 14. According to Embodiment 14 of the disclosure, any one of Embodiments 8-13 is provided, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.

Embodiment 15. According to Embodiment 15 of the disclosure, a photovoltaic module is provided that includes: an outer glass layer; an inner glass layer; a plurality of photovoltaic (PV) structures disposed on the outer glass layer; and a polymeric encapsulant disposed over the plurality of PV structures and between the inner and outer glass layers. The outer glass layer has a thickness of from 100 to 600 μm and the inner glass layer has a thickness of from 2.1 to 5 mm. Further, the polymeric encapsulant has an elastic modulus of from 0.1 MPa to 10 MPa and a thickness of from 0.01 to 0.2 mm.

Embodiment 16. According to Embodiment 16 of the disclosure, Embodiment 15 is provided, wherein the module exhibits a failure probability (P_{f}) of less than 15% upon exposure to an ice ball having a 1 inch diameter with an impact energy of 5 Joules according to the IEC 61215 & ASTM E1038 Hail Test.

Embodiment 17. According to Embodiment 17 of the disclosure, Embodiment 15 is provided, wherein the module exhibits a failure probability (P_{f}) of less than 2% upon exposure to an ice ball having a 1 inch diameter with an impact energy of 5 Joules according to the IEC 61215 & ASTM E1038 Hail Test.

Embodiment 18. According to Embodiment 18 of the disclosure, any one of Embodiments 15-17 is provided, wherein the encapsulant comprises one or more adhesives selected from the group consisting of silicone, thermoplastic polyurethane (TPU) and ethylene vinyl acetate (EVA) adhesives.

Embodiment 19. According to Embodiment 19 of the disclosure, any one of Embodiments 15-18 is provided, wherein each of the glass layers exhibits a coefficient of thermal expansion (CTE) of less than 10 ppm/° C. and the polymeric encapsulant exhibits a CTE of 50 to 200 ppm/° C.

Embodiment 20. According to Embodiment 20 of the disclosure, any one of Embodiments 15-19 is provided, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

Embodiment 21. According to Embodiment 21 of the disclosure, any one of Embodiments 15-20 is provided, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.

1. A photovoltaic module, comprising:
an outer glass layer;
an inner glass layer;
a plurality of photovoltaic (PV) structures disposed on the outer glass layer; and
a polymeric encapsulant disposed over the plurality of PV structures and between the inner and outer glass layers,
wherein the outer glass layer is at least three times thinner than the inner glass layer, and
further wherein the module exhibits a failure probability (P_{f}) of less than 15% upon exposure to an ice ball having a 1 inch diameter with an impact energy of 5 Joules according to the IEC 61215 & ASTM E1038 Hail Test.

2. The module according to claim 1, wherein the module exhibits a failure probability (P_{f}) of less than 2% upon exposure to an ice ball having a 1 inch diameter with an impact energy of 5 Joules according to the IEC 61215 & ASTM E1038 Hail Test.

3. The module according to claim 1, wherein the module exhibits no failures upon exposure to an ice ball having a 1.75 inch diameter with a velocity of 30 m/s according to the IEC 61215 & ASTM E1038 Hail Test.

4. The module according to claim 1, wherein the encapsulant comprises one or more adhesives selected from the group consisting of silicone, ionomer, thermoplastic polyolefin (TPO), polyolefin (PO), polyvinyl butyral (PVB), thermoplastic polyurethane (TPU), and ethylene vinyl acetate (EVA) adhesives.

5. The module according to claim 1, wherein each of the glass layers exhibits a coefficient of thermal expansion (CTE) of less than 10 ppm/° C. and the polymeric encapsulant exhibits a CTE of 50 to 200 ppm/° C.

6. The module according to claim 1, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

7. The module according to claim 1, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.

8. A photovoltaic module, comprising:
an outer glass layer;
an inner glass layer;
a plurality of photovoltaic (PV) structures disposed on the outer glass layer; and
a polymeric encapsulant disposed over the plurality of PV structures and between the inner and outer glass layers,
wherein the outer glass layer has a thickness of from 100 to 600 μm and the inner glass layer has a thickness of from 2.1 to 5 mm, and
further wherein the polymeric encapsulant has an elastic modulus of from 100 MPa to 1000 MPa and a thickness of from 0.2 to 0.5 mm.

9. The module according to claim 8, wherein the module exhibits a failure probability (P_{f}) of less than 15% upon exposure to an ice ball having a 1 inch diameter with an impact energy of 5 Joules according to the IEC 61215 & ASTM E1038 Hail Test.

10. The module according to claim 8, wherein the module exhibits a failure probability (P_{f}) of less than 2% upon exposure to an ice ball having a 1 inch diameter with an impact energy of 5 Joules according to the IEC 61215 & ASTM E1038 Hail Test.

11. The module according to claim 8, wherein the encapsulant comprises one or more adhesives selected from the group consisting of thermoplastic polyolefin (TPO), polyolefin (PO), ionomer, and polyvinyl butyral (PVB) adhesives.

12. The module according to claim 8, wherein each of the glass layers exhibits a coefficient of thermal expansion (CTE) of less than 10 ppm/° C. and the polymeric encapsulant exhibits a CTE of 50 to 200 ppm/° C.

13. The module according to claim 8, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

14. The module according to claim 8, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.

15. A photovoltaic module, comprising:
an outer glass layer;
an inner glass layer;
a plurality of photovoltaic (PV) structures disposed on the outer glass layer; and
a polymeric encapsulant disposed over the plurality of PV structures and between the inner and outer glass layers,
wherein the outer glass layer has a thickness of from 100 to 600 μm and the inner glass layer has a thickness of from 2.1 to 5 mm, and
further wherein the polymeric encapsulant has an elastic modulus of from 0.1 MPa to 10 MPa and a thickness of from 0.01 to 0.2 mm.

16. The module according to claim 15, wherein the module exhibits a failure probability (P_{f}) of less than 15% upon exposure to an ice ball having a 1 inch diameter with an impact energy of 5 Joules according to the IEC 61215 & ASTM E1038 Hail Test.

17. The module according to claim 15, wherein the module exhibits a failure probability (P_{f}) of less than 2% upon exposure to an ice ball having a 1 inch diameter with an impact energy of 5 Joules according to the IEC 61215 & ASTM E1038 Hail Test.

18. The module according to claim 15, wherein the encapsulant comprises one or more adhesives selected from the group consisting of silicone, thermoplastic polyurethane (TPU) and ethylene vinyl acetate (EVA) adhesives.

19. The module according to claim 15, wherein each of the glass layers exhibits a coefficient of thermal expansion (CTE) of less than 10 ppm/° C. and the polymeric encapsulant exhibits a CTE of 50 to 200 ppm/° C.

20. The module according to claim 15, wherein each PV structure is one of a CdTe, amorphous silicon (a-Si), polysilicon (p-Si), CuIn/GaSe (CIGS), organic small molecule, organic polymer, and perovskite (ABX₃) thin-film PV structure.

21. The module according to claim 15, wherein the outer glass layer comprises outer and inner primary surfaces, and further wherein the outer glass layer comprises a compressive stress region defined from the outer primary surface to a depth of layer (DOL) of at least 20% of a thickness of the outer glass layer and comprising a compressive stress of at least 800 MPa.
